(19) United States
(12) Patent Application Publication
(10) Pub. No.: US 2023/0161577 A1
(43) Pub. Date: May 25, 2023

(54) GENERATING AND VERIFYING INSTRUCTIONS FOR A RETAIL SEARCH APPLIANCE

(71) Applicant: ENT. SERVICES DEVELOPMENT CORPORATION LP, Houston, TX (US)

(72) Inventors: Horst STOHRER, Belmont, CA (US); Praveen CHERUKURI, Lakeland, FL (US); Joseph ZAMZOW, Lakeland (US)

(73) Assignee: ENT. SERVICES DEVELOPMENT CORPORAION LP, Houston, TX (US)

(21) Appl. No.: 18/101,479

(22) Filed: Jan. 25, 2023

Related U.S. Application Data
(63) Continuation of application No. 17/575,895, filed on Jan. 14, 2022, now abandoned.
Application No. 17/575,895 is a continuation of application No. 17/087,230, filed on Nov. 2, 2020, now abandoned.
Application No. 17/087,230 is a continuation of application No. 15/776,399, filed on May 15, 2018, now abandoned.

(51) Int. Cl. G06F 8/41; G06Q 30/02; G06Q 30/0283; G06Q 10/02; G06Q 10/04; G06F 30/34; G06F 30/327

(52) U.S. Cl. CPC G06F 8/447; G06Q 30/02; G06Q 30/0283; G06Q 10/02; G06Q 10/04; G06F 30/34; G06F 30/327; G06F 8/443

(57) ABSTRACT

Example implementations relate to processing of retail offerings and retail rules for implementation in a retail appliance. For example, retail rules and retail offerings may be translated into a retail offer domain-specific language (DSL). The translated retail rules and retail offerings may be expressed as constraints according to a satisfiability module theory (SMT) language. A hardware-optimized description of the translated retail rules and retail offerings may be generated that satisfy the constraints, and computer-executable instructions may be generated, based on the hardware-optimized description.

### CROSS-REFERENCE TO RELATED APPLICATIONS

This application is a continuation of U.S. application Ser. No. 17/087,230, filed Nov. 2, 2020 which is a continuation of U.S. application Ser. No. 15/776,399, filed May 15, 2018, which is a national stage application pursuant to 35 U.S.C. § 371 of International Application No. PCT/US2015/061934, filed Nov. 20, 2015, the disclosure of which is hereby incorporated by reference herein by their entireties.

### BACKGROUND

Retail offerings often rely heavily on rules and constraints to provide for restrictive pricing. For example, an airline offering may contain a particular fare subject to a rule or constraint that the corresponding trip spans only a weekend. Such restricted pricing is increasingly being employed in other retail product spaces, such as online retailing, where offers are discounted on specific combinations of products or to specific types of users. Such systems are highly complex. For example, airline flight search has been demonstrated to be an NP-Complete (or nondeterministic polynomial time complete) problem space. In terms of computation complexity for a given problem, NP-complete signifies that the time required to solve a problem using increases (often exponentially) as the size of the problem grows.

### BRIEF DESCRIPTION OF THE DRAWINGS

FIG. 1 illustrates an example retail search system in which the described examples may be implemented.

FIG. 2 illustrates an example method for generating computer-executable instructions for execution by a retail appliance, according to the present examples.

FIG. 3 illustrates an example computer system upon which embodiments described herein may be implemented.

FIG. 4 is an example block diagram of several sample aspects of apparatuses configured to process retail rules and retail offerings as taught herein.

### DETAILED DESCRIPTION

Searching retail offerings is becoming increasingly complicated due to restricted pricing, business rules and constraints, bundling, personalization, and so on. This is true for airline flight search, which has already been demonstrated to be an NP-Complete problem space, but is also true for other retail spaces, as similar rules, constraints, and personalization options are introduced. Among other benefits, examples described provide an efficient solution to the complexity of searching retail offerings for air fares and other products. Additionally, examples further recognize that in the space of retail search for airfares, accurate and up-to-date results are needed in order to avoid inaccurate search results, results which incorporate stale data, and other negative outcomes which may otherwise affect the profitability of the product. Accordingly, examples such as described provide accurate and efficient hardware and software solutions for searching airfare and retail offerings.

Satisfiability modulo theory (SMT) solving has been developed to provide symbolic reasoning about systems and computations. An SMT instance is a logical formula expressed according to a mathematical theory, and the SMT problem is determining whether the formula is satisfiable. Such mathematical theories may include the theory of real numbers, the theory of integers, the theories of data structures such as bit vectors and arrays, and so on. Theories which may be particularly useful for use with the present examples may include the theories of arithmetic, fixed size arrays and fixed-size bit vectors. Each theory may allow for different types of operations. For example, the theory of bit vectors may allow for: string-like operations including concatenation, extraction, and so on; logical operations such as bitwise and, or, not, and so on; and arithmetic operations such as addition, subtractions, multiplication, and so on. In practice, theories may be combined in a single formula.

SMT solvers include algorithmic approaches which have been used in software verification, symbolic analysis, program verification, automatic testing, and other fields. Recent developments in SMT solvers have provided the ability to address increasingly difficult problem domains. For example, SMT solvers implement algorithms which guess a value of a propositional variable, in order to simplify a formula. If the guess is wrong, the algorithm may backtrack. SMT solvers implement intelligent rules for guessing, simplifying and backtracking a propositional value may be used to achieve less complex operations for purpose of solving a larger problem. Additionally, SMT solvers can be employed to find a maximum value of a fixed-size bit vector or array.

Examples such as described enable the generation of verified instructions for execution by a retail appliance. Such instructions may be generated by appropriately translating retail offerings and retail rules for use with a retail appliance. By virtue of examples as described, retail rules and retail offerings may be translated into a retail offer domain-specific language (DSL). The translated retail offerings and retail rules may also be expressed as constraints according to a satisfiability modulo theory (SMT) language. A hardware-optimized description of the translated retail offerings and retail rules may also be generated. A determination may be made whether or not the hardware-optimized description correctly processes all retail rules. Computer-executable instructions may be generated based on the hardware-optimized description, if the hardware-optimized description correctly processes the retail rules.

In other variations, examples are implemented using instructions that are stored with a non-transitory computer-readable storage medium and are executable by a processor to cause the processor to perform an example method as described.

In other examples, an electronic device for processing retail rules and retail offerings is described. Such a device may include a domain-specific language (DSL) translation engine, for translating retail offerings and retail rules into a retail offer DSL. A satisfiability modulo theory (SMT) engine may express translated retail offerings and retail rules as constraints according to an SMT language. A hardware-optimized description engine may generate a description of the translated retail offerings and retail rules, the description optimized for implementation in a programmable hardware device of a retail appliance. A verification module may verify that the optimized description correctly processes the retail rules. If the optimized description correctly processes the retail rules, a hardware description generation engine may generate computer-executable instructions based on the optimized description.

Aspects described herein provide that methods, techniques and actions performed by a computing device are performed programmatically, or as a computer-implemented method. Programmatically means through the use of code, or computer-executable instructions. A programmatically performed step may or may not be automatic.

Examples described herein can be implemented using engines, which may be any combination of hardware and programming to implement the functionalities of the engines or components. In examples described herein, such combinations of hardware and programming may be implemented in a number of different ways. For example, the programming for the components may be processor executable instructions stored on a non-transitory machine-readable storage medium and the hardware for the components may include a processing resource to execute those instructions. In such examples, the machine-readable storage medium may store instructions that, when executed by the processing resource, implement the engines or components. In examples, a system may include the machine-readable storage medium storing the instructions and the processing resource to execute the instructions, or the machine-readable storage medium may be separate but accessible to the system and the processing resource.

Furthermore, aspects described herein may be implemented through the use of instructions that are executable by a processor or combination of processors. These instructions may be carried on a non-transitory computer-readable medium. Machines shown or described with figures below provide examples of processing resources and computer-readable mediums on which instructions for implementing some aspects can be carried and/or executed. In particular, the numerous machines shown in some examples include processor(s) and various forms of memory for holding data and instructions. Examples of computer-readable mediums include permanent memory storage devices, such as hard drives on personal computers or servers. Other examples of computer storage mediums include portable storage units, such as CD or DVD units, flash or solid state memory (such as carried on many cell phones and consumer electronic devices) and magnetic memory. Computers, terminals, network enabled devices (e.g., mobile devices such as cell phones) are all examples of machines and devices that utilize processors, memory, and instructions stored on computer-readable mediums. Additionally, aspects may be implemented in the form of computer programs.

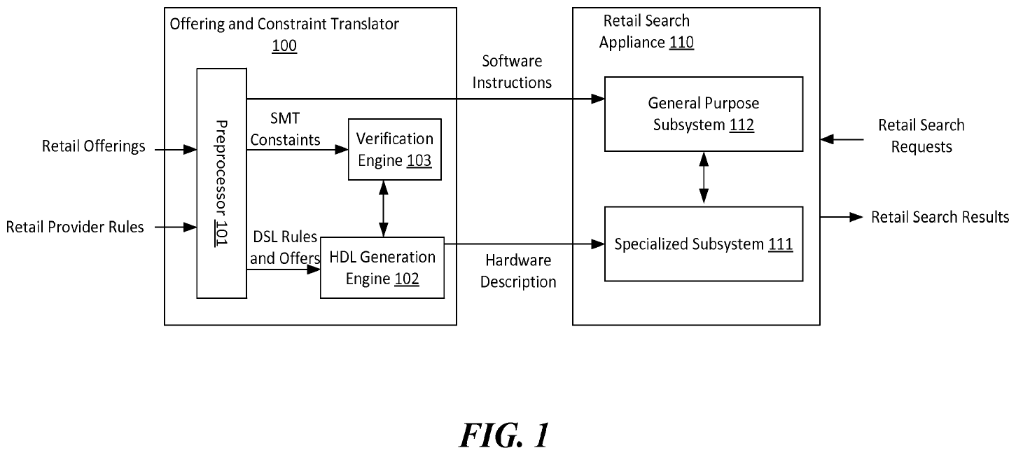

FIG. 1 illustrates an example of a retail search system in which the described examples may be implemented. The retail search system may include an offering and constraint translator 100, containing a preprocessor 101 an hardware description language (HDL) generation engine 102, and a verification engine 103, and a retail search appliance 110, containing a specialized subsystem 111 and a general purpose subsystem 112. In accordance with some examples, preprocessor 101 may receive retail offerings and retail provider rules. The retail offerings and retail provider rules may be provided to preprocessor 101 through various sources, including retail industry feeds. In some examples, preprocessor 101 may process the retail offerings into priceable units (PUs). In some other examples, another computer system may pre-process the retail offerings into PUs.

In accordance with some examples, the retail offerings and retail rules may be related to air travel. In such examples, the retail offerings may include fare components, as described above, and may be in the form of itineraries, industry feed-based fares (such as ATPCO-based fares), and so on. The retail provider rules may include seat maps, fare routes, fare rules, or other appropriate business rules associated with the retail offerings. For example, for air travel retail searches, such retail provider rules may include Saturday night stay requirements, advance purchase requirements, and other time-dependent rules, as described below. The retail provider rules may also include passenger-related rules (e.g., fares for children, frequent fliers, companion fares etc.). Additionally, the retail provider rules may include global constraints, such as a requirement that a first class ticket be sufficiently more expensive than an economy class ticket. Some important structures such as seat maps, fare routes, may be expressed as bit vectors. For example an origin airport may be represented with an 8 bit value, a destination the same, and a flag indicating whether or not it is a round trip a single bit. In this example, a custom hardware architecture supporting an optimized 17 bit word size for the input may be created. Other structures, such as itineraries and fare rules may be represented as arrays. In some other examples, preprocessor 101 may receive additional information about fare and flight availability, for example a code vector may be received for a flight, characterizing seat availability for the flight.

In some examples of FIG. 1, after receiving the retail offerings and retail provider rules, and processing the retail offerings into PUs, preprocessor 101 may translate the retail offers and the retail provider rules into a retail offer domain-specific language (DSL). A DSL is a computer language specialized to a particular application domain, in contrast to a general-purpose language, which may be applicable to a number of application domains. Some widely used DSLs include hypertext markup language (HTML), VHDL for hardware description, and Mathematica for symbolic mathematics. A retail offer DSL may be specialized to a particular retail space, such as an air travel retail space. DSLs for the air travel retail space may allow for efficient and correct expression of retail offerings and retail rules for air travel retail space. For example, such DSLs may provide expression of origin and destination airports, where the value of each expressed airport is limited to values selected from a list of valid airport codes. Additionally, such DSLs may provide for the expression of fare components, for the expression of combinations of fare components into valid itineraries, and so on. As described above, such DSLs may provide for the expression of itineraries and fare rules as arrays. For example, the DSL may support combinators for stating two expressions are equal, less than or greater than. The DSL may direct the building of an abstract syntax tree (AST) from literals (the data values such as origin, destination, and journey segments for example), and then successively combine these with operators to form rule expressions. These rules may be further combined to provide successively more complex restricted offers. The resulting data structure (AST) may initially form a directed graph usable for further translation and optimization. The optimized (translated) representation of these, may for example, be expressed as an array including an ordered set of fare components. Other relevant structures such as seat maps and fare routes may be expressed as bit vectors.

After translating the retail offerings and retail provider rules into the retail offer DSL, preprocessor 101 may generate one or more constraints according to an SMT language, based on the translated retail offerings and retail provider rules. Generating the SMT constraints may allow for the rules to be translated into lower level satisfiability problems, and may allow for important optimizations to be made for tackling highly complex retail search problems (e.g., NP-Complete problems such as air travel search). Preprocessor 101 may also remove quantifiers from the resulting mathematical expressions such as “forall,” “exists” and other functions which may process over multiple elements. These functions may be comparatively expensive for an SMT solver. Such functions may be more efficiently performed in a recursive manner by software outside of the SMT solver. Accordingly, preprocessor 101 may differentiate between application functions which require inductive or recursive processing, from those which process over fixed-size or bounded data.

After translating the retail offers and retail provider rules into the retail offer DSL, preprocessor 101 may send the translated rules and offers to HDL generation engine 102. HDL generation engine 102 may then inspect the translated rules and offers. This may include walking or traversing the abstract syntax tree (AST). This may allow for the translation of functions containing logical connectors, integer comparisons, and bit-level operations (e.g., on bit vectors) to be translated into an HDL such as VHDL or Verilog. In some examples, this may be accomplished using a high-level representation of the HDL (e.g., Chalmers Lava). This high level representation of the HDL may be created using another DSL, representing the circuit description as an AST which may be translated to SMT for further verification or into synthesizable VHDL code.

HDL generation engine 102 may generate a hardware description corresponding to the translated rules and offers. This hardware description can be optimized for implementation in specialized subsystem 111 of retail search appliance 110. In some examples, the hardware description may be optimized for implementation in specialized subsystem 111 by having a word size based on a size of one type of retail object in the translated retail offerings and retail rules. For example, the hardware description may have a word size corresponding to a number of bits in a fare component in the retail offer DSL. In some other examples, the hardware description may be optimized for a number of processing cores corresponding to a maximum expected number of fare components in an itinerary. Including this number of processing cores may allow for each fare component of an itinerary to be processed in parallel. In some examples, HDL generation engine 102 may develop a pipelined microcode in order to increase throughput of the hardware description by allowing increased clock speed.

The optimized HDL description—which may be represented as an AST—generated by HDL generation engine 102 may be translated into SMT for verification in verification engine 103.

Although the HDL description is optimized for implementation in specialized subsystem 111, this optimized HDL description should still satisfy the retail provider rules. Accordingly, HDL generation engine 102 may verify that the optimized HDL description satisfies the rules using verification engine 103. Verification engine 103 may translate the optimized HDL description into the SMT language, and compare this translated optimized HDL description to the SMT constraints generated by preprocessor 101. Verification engine 103 may then compare the two models using an SMT solver, which may produce a proof that each SMT model processes the retail provider rules with equivalent results. This may be an improvement over verification methods using software testing alone, since such software testing becomes increasingly difficult as rules become more complex.

After generating the hardware description, and verifying the hardware description using verification engine 103, HDL generation engine 102 may transmit the hardware description for implementation on a specialized subsystem 111 of a retail search appliance 110. Specialized subsystem 111 may be a digital logic circuit, such as an FPGA, and implementing the HDL on the FPGA may include generating a netlist, and mapping the netlist to the FPGA. In some examples, specialized subsystem may include multiple FPGAs, which may be multiple accelerated FPGAs, to allow for parallel processing of search requests.

In some examples, preprocessor 101 of offering and constraint translator 100 may also transmit software instructions to a general purpose subsystem 112 of retail search appliance 110. General purpose subsystem may be coupled to specialized subsystem 111 (e.g., via a hardware bus such as a PCI Express (PCIe) hardware bus). In example retail appliances where specialized subsystem 111 includes multiple FPGAs, each FPGA may be coupled to general purpose subsystem 111 via a hardware bus such as a PCIe bus. General purpose subsystem 112 may include a general purpose processor such as a CPU. General purpose subsystem 112 may receive retail search requests from a user. In some examples, Retail search appliance 110 may be hosted in a cloud environment, and provide functionality through a Software as a Service (SaaS) API using internet protocols. In some examples, the SaaS layer may be implemented using Java or .NET running on the general-purpose subsystem 112. The SaaS layer may handle the network protocols and application processing, and may also be responsible for communications with the retail appliance system RAM. In some examples general purpose subsystem 112 may transfer data to specialized subsystem 111 from system RAM through the use of a direct memory access (DMA) based driver operating over a hardware bus such as a PCIe bus.

In accordance with the present examples, a retail search request may be received from a remote user using the internet protocols. For example, a retail search may include a request to determine a lowest priced fare given a set of fares and an itinerary. General purpose subsystem 112 may determine which functions of each retail search require inductive or recursive processing from functions which process over fixed size or bounded data. Functions which require inductive or recursive processing may be performed by software, for example using a CPU of general purpose subsystem 112. In other examples, functions requiring inductive or recursive processing may be performed using a separate computing device of retail appliance 110 (not shown in FIG. 1 for simplicity). Functions which process over bounded or fixed size data may be performed by specialized subsystem 111 (e.g., using the verified hardware description generated by HDL generation engine 102). For example, data relating to such functions may be sent to specialized subsystem 111 (e.g., over a hardware bus such as a PCIe bus). After processing the bounded or fixed size data, specialized subsystem 111 may return an output to general purpose subsystem 112 via the hardware bus. The output may be combined with the results of the inductive or recursive processing in order to generate retail search results. In some examples, multiple results to a retail search may be desired. When multiple results are desired, after determining a best solution, this solution may be added to a constraint list (thus removing it as a possible search result), and a next best result may be determined. This process may be repeated to determine the desired number of search results. When retail search results have been determined, general purpose subsystem 112 may provide the search results to the requesting user (e.g., via the internet protocols). The user may then select a search result for purchase. For example, if the retail search is an air travel search, the user may select a search results for purchase using an airline's web site, or using an online travel store.

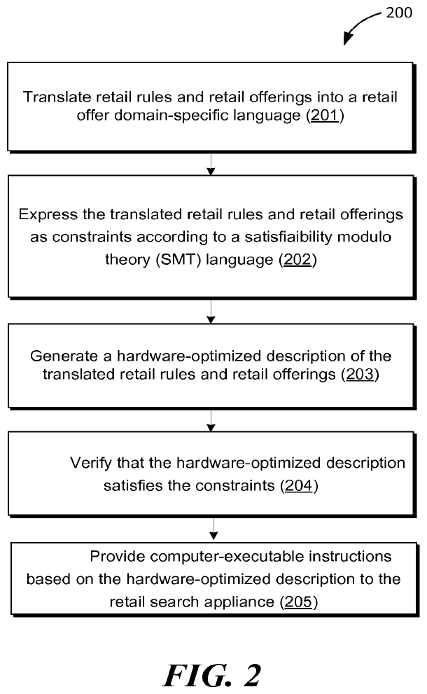

FIG. 2 illustrates an example method 200 for generating computer-executable instructions for execution by a retail appliance, according to the present examples. Method 200 may be implemented in the form of executable instructions stored on a machine readable storage medium and executed by a processing resource and/or in the form of electronic circuitry. For example, method 200 may be described below as being executed or performed by the offering and constraint translator 100 of FIG. 1.

In accordance with some examples, retail rules and retail offerings may be translated into a retail offer domain-specific language (DSL) (201). In some examples, the retail offerings and retail rules may be translated by preprocessor 101 of FIG. 1. In some examples, translating the retail rules and retail offerings may include preprocessing the retail offerings into priceable units, and generating constraints for each priceable unit based on the retail rules. The retail offerings and retail rules may be air travel offerings and air travel rules. If the offerings are air travel offerings, then the retail offerings may include fare components, and may be represented as arrays. Additionally, the retail rules may include air fare rules, and may also be represented as arrays. The retail rules may include geometrical restrictions, where each priceable unit includes fare components matching at least one geometrical restriction.

The retail rules and retail offerings may be expressed as constraints according to a satisfiability modulo theory (SMT) language (202). In some examples, this expression may be performed by preprocessor 101 of FIG. 1.

After the retail offerings and retail rules have been expressed according to an SMT language, a hardware-optimized description of the translated retail rules and retail offerings may be generated (203). In some examples, this may be performed by HDL generation engine 102 of FIG. 1. In some examples, the hardware-optimized description may be expressed according to an HDL such as VHDL. According to some examples, the hardware-optimized description may have a word size based, at least in part, on a size of a retail offering.

The hardware-optimized description may then be verified, to determine whether or not it satisfies the constraints (204). In some examples, this may be performed by verification engine 103 of FIG. 1. If the hardware-optimized description satisfies the constraints, computer-executable instructions may be generated, based on the hardware-optimized description. If the hardware-optimized description does not satisfy the constraints, the computer-executable instructions may not be generated. In some examples, a notification may be generated, indicating that that the hardware-optimized description does not satisfy the constraints. If the constraints are satisfied, computer-executable instructions may be generated by HDL generation engine 102 of FIG. 1. In some examples, generating the computer-executable instruction may include generating a set of software instructions for execution by a general-purpose processor of the retail appliance, and generating a circuit description for configuration of a hardware device of the retail appliance. The hardware device may be a field-programmable gate array (FPGA) and the circuit description may be a netlist. In some examples, the software instructions may include inductive or recursive operations based on the hardware-optimized description, and the circuit description may include operations which process over fixed-size data. The computer-executable instructions may then be provided to the retail search appliance for execution (205).

Examples as described above with respect to the retail search system of FIG. 1 and the method 200 of FIG. 2 can be used in a variety of retail spaces. One retail space is the air travel search space. The highly complex pricing structures of air travel fares may be efficiently and accurately represented for search using example retail devices.

The basic unit of price in air travel is the fare. A fare is a price offered for one-way travel between two cities. This fare may often be the same for travel in either direction between the two cities. Each fare may be published with a set of rules and restrictions regarding its use. While each flight may be paid for by one fare, a single fare may pay for more than one flight. A fare component (FC) refers to a fare and the flights it pays for. A traveler may choose fare combinations for a ticket as long as all fare rules are satisfied. Often, a traveler may wish to select the least expensive combination of fares, but may wish to select more expensive fares (e.g., first class fares, or refundable fares).

Multiple fare components may be combined into a single priceable unit (PU). A PU is a collection of one or more fare components, and represents the smallest group of flights and fares which may be sold on its own. Generally PUs are limited to a specified group of geometries. For example, typical PU geometries may include: one way PUs including a single fare component; round trip or circle trip PUs which may be built from a number of fare components forming a loop; and open jaw PUs which form a loop with one fare component missing. Assuming 4 destinations A, B, C, and D, an example one-way PU may include a single fare component A to B. An example round trip PU may include two fare components—one A to B and the other B to A. An example circle trip PU may include 3 fare components—one A to B, a second B to C, and a third C to A. An example open jaw PU may include 3 fare components— one A to B, a second B to C, and a third C to D.

A variety of fare rules may apply to different PUs. For example, a Saturday night stay restriction may apply to PUs having relatively inexpensive fares. Such a restriction may require that there be a Saturday night between the departure of the first flight in the first fare component and the departure of the first flight in the last fare component of the PU. Other example fare restrictions may require that all fares in a PU be on the same airline, may require that a PU be a round-trip PU to qualify for an inexpensive fare, or may require the PU be purchased a specified number of days in advance. Additionally, fare rules may restrict combinations of fare components within a PU, such as fare rules which require other fares in the same PU to be on the same airline, and rules which provide restrictions on the flight numbers, locations, or departure times of flights.

Additional fare rules may restrict which passengers may be eligible to use a given fare. For example, fare rules may provide for discounts to children, travel agents, senior citizens, frequent fliers, and so on. Other fare rules may allow one passenger's fare to restrict another's—for example, a rule may provide for a discounted companion fare for a second passenger, provided those passengers pay for the fares in the same transaction.

PUs and fare rules are responsible for much of the complexity of the air travel search space. For example, the variety of ways different fare components may be grouped into PUs increases the size of the search space. Additionally, the use of fare rules in PUs may introduce long-distance dependencies between different parts of a trip. For example, a Saturday night stay fare rule may introduce a constraint on the departure times of two flights which are widely separated in time and distance. The presence of multiple passengers on a trip may also significantly increase the complexity of the search, due to the presence of fare rules such as companion fares.

Seat availability and inventory may further complicate an air travel search, as airlines may use seat availability to dynamically adjust prices. Each published fare may be assigned a letter, called a booking code, generally based on the fare's cabin (e.g., coach, business or first) and the fare's price. A code vector may express the number of available seats for each booking code. The above-described techniques may efficiently represent and process these air travel rules and offerings because of the complexity of the offerings, and because, while highly complex, the rules and offerings involve processing over bounded data, often involving data structures of fixed size (e.g., an aircraft may have a fixed number of seats, there may be a fixed number of airports, and so on).

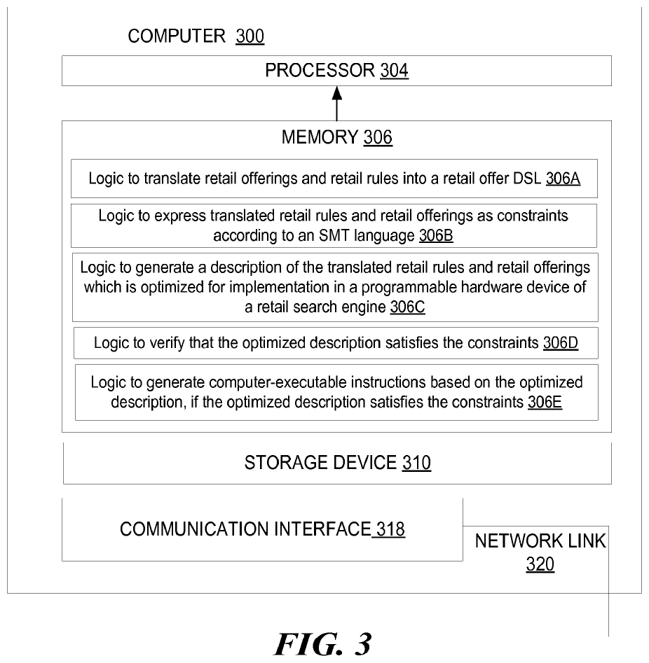

FIG. 3 is a block diagram that illustrates a computer system upon which embodiments described herein may be implemented. For example, in the context of FIG. 1, offering and constraint generator 100 may be implemented using one or more computers such as described by FIG. 3.

In an embodiment, computer system 300 includes processor 304, memory 306 (including non-transitory memory), storage device 310, and communication interface 318. Computer system 300 includes at least one processor 304 for processing information. Computer system 300 also includes the memory 306, such as a random access memory (RAM) or other dynamic storage device, for storing information and instructions to be executed by processor 304. For example, instructions stored in memory 306 may be executed to implement the method 200. In some examples, memory 306 can store (i) logic 306A for translating retail offerings and retail rules into a retail offer DSL, (ii) logic 306B for expressing translated retail rules and retail offerings as constraints according to an SMT language, (iii) logic 306C for generating a description of the translated retail rules and retail offerings which is optimized for implementation in a programmable hardware device of a retail search engine, (iv) logic 306D for verifying that the optimized description satisfies the constraints, and (v) logic 306E for generating computer-executable instructions based on the optimized description, if the optimized description satisfies the constraints, in accordance with some aspects.

Memory 306 also may be used for storing temporary variables or other intermediate information during execution of instructions to be executed by processor 304. Computer system 300 may also include a read only memory (ROM) or other static storage device for storing static information and instructions for processor 304. The storage device 310, such as a magnetic disk or optical disk, is provided for storing information and instructions. The communication interface 318 may enable the computer system 300 to communicate using a network (e.g., for transmitting computer-executable instructions to a retail search appliance 110 as in FIG. 1) through use of the network link 320 and any one of a number of well-known transfer protocols (e.g., Hypertext Transfer Protocol (HTTP)). Examples of networks include a local area network (LAN), a wide area network (WAN), the Internet, mobile telephone networks, Plain Old Telephone Service (POTS) networks, and wireless data networks (e.g., Wi-Fi and WiMAX networks).

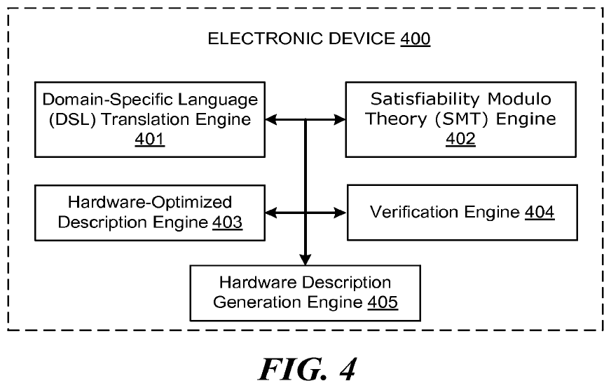

FIG. 4 shows an example electronic device 400 for processing retail rules and retail offerings, represented as a series of interrelated engines. With respect to FIG. 4, the electronic device 400 may include: a domain-specific language (DSL) translation engine 401, for translating retail offerings and retail rules, into a retail offer DSL; a satisfiability modulo theory (SMT) engine 402, for expressing the translated retail rules and retail offerings as constraints according to an SMT language; a hardware-optimized description engine 403, for generating a description of the translated retail rules and retail offerings which is optimized for implementation in a programmable hardware device of a retail search appliance; a verification engine 404, for verifying that the optimized description satisfies the constraints; and a hardware description generation engine 405, for generating computer-executable instructions for transmission to and execution by the retail search appliance, where the instructions are based on the optimized description. In some examples, each of the engines of FIG. 4 may be implemented by appropriate hardware and software. For example, the functions of DSL translation engine 401 and SMT engine 402 may be provided by preprocessor 101 of FIG. 1. The functions of hardware-optimized description engine 403 and hardware description generation engine 405 may be provided using HDL generation engine 102 of FIG. 1. Similarly, the functions of verification engine 404 may be provided using verification engine 103 of FIG. 1.

Although illustrative aspects have been described in detail herein with reference to the accompanying drawings, variations to specific examples and details are encompassed by this disclosure. It is intended that the scope of examples described herein be defined by claims and their equivalents. Furthermore, it is contemplated that a particular feature described, either individually or as part of an embodiment, can be combined with other individually described features, or parts of other aspects. Thus, absence of describing combinations should not preclude the inventor(s) from claiming rights to such combinations.

1. A method for generating verified instructions for execution by a retail search appliance, the method comprising:
translating retail rules and retail offerings into a retail offer domain-specific language (DSL);
expressing the translated retail rules and retail offerings as constraints according to a satisfiability modulo theory (SMT) language;
generating a hardware-optimized description of the translated retail rules and retail offerings;
verifying that the hardware-optimized description of the translated retail rules and retail offerings satisfies the constraints; and
providing computer-executable instructions that are based on the hardware-optimized description to the retail search appliance for execution, wherein the providing computer-executable instructions includes (i) generating a set of software instructions for execution by a general-purpose processor of the retail search appliance, the set of software instructions including inductive or recursive operations based on the hardware-optimized description, and (ii) generating a circuit description for configuration of a hardware device of the retail search appliance, the circuit description including operations which process over fixed-size data.

2. The method of claim 1, wherein the hardware-optimized description has a word size based, at least in part, on a size of a retail offering.

3. The method of claim 1, wherein the hardware device is a field-programmable gate array, and the circuit description is a netlist.

4. The method of claim 1, wherein translating the retail rules and one or more retail offerings into the retail offer DSL includes pre-processing offerings into priceable units, and generating constraints for each priceable unit based on the retail rules.

5. The method of claim 4, wherein retail rules and the retail offerings are air travel retail rules and air travel retail offerings, respectively.

6. The method of claim 5, wherein the retail offerings include fare components, the fare components represented as arrays; and
the retail rules include fare rules, the fare rules represented as arrays.

7. The method of claim 6, wherein the retail rules include geometrical restrictions, wherein each priceable unit includes fare components matching at least one of the geometrical restrictions.

8. A non-transitory computer-readable storage medium that stores a set of instructions, which when executed by a processor, cause the processor to:
translate retail rules and retail offerings into a retail offer domain-specific language (DSL);
express the translated retail rules and retail offerings as constraints according to a satisfiability modulo theory (SMT) language;
generate a hardware-optimized description of the translated retail rules and retail offerings;
verify that the hardware-optimized description satisfies the constraints; and
if the hardware-optimized description satisfies the constraints, generate computer-executable instructions based on the hardware-optimized description for transmission to a retail search appliance for execution, wherein execution of the instructions to generate the computer-executable instructions cause the processor further to (i) generate a set of software instructions for execution by a general-purpose processor of the retail search appliance, the set of software instructions including inductive or recursive operations based on the hardware-optimized description, and (ii) generate a circuit description for configuration of a hardware device of the retail search appliance, the circuit description including operations which process over fixed-size data.

9. The non-transitory computer-readable storage medium of claim 8, wherein the hardware-optimized description has a word size based, at least in part, on a size of a retail offering.

10. The non-transitory computer-readable storage medium of claim 9, wherein the hardware device is a field-programmable gate array, and the circuit description is a netlist.

11. An electronic device for processing retail rules and retail offerings, the electronic device comprising a processor, causing the processor to execute:
a domain-specific language (DSL) translation engine to translate retail offerings and retail rules, into a retail offer DSL;
a satisfiability modulo theory (SMT) engine to express translated retail rules and retail offerings as constraints according to an SMT language;
a hardware-optimized description engine to generate a description of the translated retail rules and retail offerings which is optimized for implementation in a programmable hardware device of a retail search appliance;
a verification engine to verify that the optimized description satisfies the constraints; and
a hardware description generation engine to generate computer-executable instructions based on the optimized description, if the optimized description satisfies the constraints, wherein the computer-executable instructions are transmitted to the retail search appliance for execution, wherein the computer-executable instructions comprise: (i) a set of software instructions for execution by a general-purpose processor of the retail search appliance, the set of software instructions including inductive or recursive operations based on the hardware-optimized description, and (ii) a circuit description for configuration of a programmable hardware device of the retail search appliance, the circuit description including operations which process over fixed-size data.

12. The electronic device of claim 11, wherein the general purpose processor is capable of receiving retail search requests from a user, wherein the general-purpose processor transfers data to the programmable hardware device using a direct memory access (DMA) based driver operating over a hardware bus.
